(19) United States
(12) Patent Application Publication
(10) Pub. No.: US 2026/0332117 A1
(43) Pub. Date: Oct. 22, 2026

(54) WEARABLE DEVICE WITH ADAPTIVE EQUALIZATION FOR ENHANCED SPEECH NATURALNESS

(71) Applicant: BOSE CORPORATION, Framingham, MA (US)

(72) Inventors: Henrry GUNAWAN, Cambridge, MA (US); Lei CHENG, Wellesley, MA (US); Mikolaj Aleksander KEGLER, London (GB); Yang LIU, Boston, MA (US); Marko STAMENOVIC, Truro, MA (US)

(21) Appl. No.: 19/182,330

(22) Filed: Apr. 17, 2025

(51) Int. Cl. H03G 5/16; H04R 1/10

(52) U.S. Cl. CPC H03G 5/165; H04R 1/1091; H04R 2460/13

(57) ABSTRACT

Techniques, including wearable audio devices and systems implementing the techniques, for using adaptive equalization to provide enhanced speech naturalness. Such a wearable audio device may include a first sensor, a second sensor, and one or more processors. The one or more processors may be generally configured, individually or collectively, to: (i) receive, at the first sensor, a first audio signal comprising a voice audio signal from the user, (ii) receive, at the second sensor, a second audio signal comprising the voice audio signal, (iii) select, based on the first audio signal and the second audio signal, a frequency limit between the first sensor and the second sensor, (iv) estimate, based on the first audio signal and the second audio signal, a transfer function between the first sensor and the second sensor, and (v) apply an equalization based on the transfer function to a first portion of the first audio signal.

### FIELD

Aspects of the disclosure generally relate to wearable devices, and, more particularly, to techniques to enable a wearable device to provide output audio with enhanced speech naturalness using adaptive equalization.

### BACKGROUND

Wearable devices such as headphones commonly provide for two way communication, in which a wearable device can capture audio that may include user speech and output audio that includes the user speech to other devices. To capture user speech, the wearable device may use one or more sensors (e.g., microphones) located somewhere on the wearable device. However, background noise may also be present in the captured audio. For example, the microphones used to capture user speech may also capture background noise that may include speech from other speakers (e.g., other people speaking near the user), as well as other unwanted non-speech noise (e.g., sneezing, crying, laughing, or other ambient noise present in the environment surrounding the wearable device). As a result of the presence of background noise in the captured audio, the wearable device may produce suboptimal output audio.

Accordingly, methods for providing improved output audio, as well as apparatuses and systems configured to implement these methods, are desired.

### SUMMARY

All examples and features mentioned below can be combined in any technically possible way.

Aspects of the present disclosure provide a wearable audio device of a user. The wearable audio device generally includes a first sensor, a second sensor, and one or more processors being configured, individually or collectively, to: receive, at the first sensor, a first audio signal including a voice audio signal from the user; receive, at the second sensor, a second audio signal including the voice audio signal; select, based on the first audio signal and the second audio signal, a frequency limit between the first sensor and the second sensor; estimate, based on the first audio signal and the second audio signal, a transfer function between the first sensor and the second sensor; and apply an equalization based on the transfer function to a first portion of the first audio signal, where the first portion of the first audio signal corresponds to a range of frequencies lower than the frequency limit.

In aspects, the one or more processors, individually or collectively, are configured to select the frequency limit between the first sensor and the second sensor when the first audio signal and the second audio signal each include a level of noise that is below a threshold.

In aspects, the one or more processors, individually or collectively, are further configured to: band limit the first audio signal to the first portion of the first audio signal such that a second portion of the first audio signal corresponding to a range of frequencies higher than the frequency limit is removed.

In aspects, the one or more processors, individually or collectively, are further configured to one of: mix the first portion of the first audio signal with at least a first portion of the second audio signal to form a mixed audio signal, where the first portion of the second audio signal corresponds to a range of frequencies higher than the frequency limit.

In aspects, the one or more processors, individually or collectively, are further configured to: increase, using a machine-learning model or a signal processing model, a signal-to-noise ratio (SNR) of the mixed audio signal.

In aspects, to estimate the transfer function between the first sensor and the second sensor, the one or more processors are configured, individually or collectively, to use adaptive filtering.

In aspects, to estimate the transfer function between the first sensor and the second sensor, the one or more processors are further configured, individually or collectively, to denoise uncorrelated noise between the first audio signal and the second audio signal.

In aspects, the first sensor includes a bone conduction sensor.

In aspects, the bone conduction sensor includes one of: an internal microphone disposed inside an ear canal of the user, a microphone facing the ear canal, a voice band accelerometer disposed outside the ear canal, a voice pickup unit (VPU), or a feedback microphone.

In aspects, the second sensor includes an external microphone or a combination of external microphones disposed outside an ear canal of the user.

Aspects of the present disclosure are directed to a method of using a wearable audio device. The method generally includes receiving, at a first sensor of the wearable audio device, a first audio signal including a voice audio signal from a user of the wearable audio device, receiving, at a second sensor of the wearable audio device, a second audio signal including the voice audio signal, selecting, based on the first audio signal and the second audio signal, a frequency limit between the first sensor and the second sensor, estimating, based on the first audio signal and the second audio signal, a transfer function between the first sensor and the second sensor, and applying an equalization based on the transfer function to a first portion of the first audio signal, where the first portion of the first audio signal corresponds to a range of frequencies lower than the frequency limit.

In aspects, the method further includes selecting the frequency limit between the first sensor and the second sensor when the first audio signal and the second audio signal each include a level of noise that is below a threshold.

In aspects, the method further includes band limiting the first audio signal to the first portion of the first audio signal such that a second portion of the first audio signal corresponding to a range of frequencies higher than the frequency limit is removed.

In aspects, the method further includes mixing the first portion of the first audio signal with at least a first portion of the second audio signal to form a mixed audio signal, where the first portion of the second audio signal corresponds to a range of frequencies higher than the frequency limit.

In aspects, the method further includes increasing, using a trained machine-learning model, a SNR of the mixed audio signal.

Aspects of the present disclosure provide a non-transitory computer-readable medium including computer-executable instructions that, when executed by one or more processors of a wearable audio device, cause the wearable audio device to perform a method. The method generally includes: receiving, at a first sensor of the wearable audio device, a first audio signal including a voice audio signal from a user of the wearable audio device, receiving, at a second sensor of the wearable audio device, a second audio signal including the voice audio signal, selecting, based on the first audio signal and the second audio signal, a frequency limit between the first sensor and the second sensor, estimating, based on the first audio signal and the second audio signal, a transfer function between the first sensor and the second sensor, and applying an equalization based on the transfer function to a first portion of the first audio signal, where the first portion of the first audio signal corresponds to a range of frequencies lower than the frequency limit.

In aspects, the method further includes: selecting the frequency limit between the first sensor and the second sensor when the first audio signal and the second audio signal each include a level of noise that is below a threshold.

In aspects, the method further includes: band limiting the first audio signal to the first portion of the first audio signal such that a second portion of the first audio signal corresponding to a range of frequencies higher than the frequency limit is removed.

In aspects, the method further includes: mixing the first portion of the first audio signal with at least a first portion of the second audio signal to form a mixed audio signal, where the first portion of the second audio signal corresponds to a range of frequencies higher than the frequency limit.

In aspects, the method further includes: increasing, using a trained machine-learning model, a SNR of the mixed audio signal.

Two or more features described in this disclosure, including those described in this summary section, may be combined to form implementations not specifically described herein.

The details of one or more implementations are set forth in the accompanying drawings and the description below. Other features, objects, and advantages will be apparent from the description and drawings, and from the claims.

### BRIEF DESCRIPTION OF THE DRAWINGS

FIG. 1 illustrates an example system, in which aspects of the present disclosure may be implemented.

FIG. 2 illustrates an exemplary wireless audio device, in which aspects of the present disclosure may be implemented.

FIG. 3 illustrates example operations for speech enhancement performed by a device, according to certain aspects of the present disclosure.

FIG. 4 is a block diagram of an example process flow for speech enhancement during the operations of FIG. 3, according to certain aspects of the present disclosure.

Like numerals indicate like elements.

### DETAILED DESCRIPTION

Certain aspects of the present disclosure provide techniques, including devices and systems implementing the techniques, for using adaptive equalization to provide output audio with enhanced speech naturalness. Such techniques may involve receiving (e.g., capturing) audio signals at two (or more) sensors included in a device. For example, a first sensor may be implemented by an internal sensor (e.g., a bone conduction sensor and/or transducer) and may receive a first audio signal, and a second sensor (or two or more second sensors) may be implemented by an external sensor located outside of the device (e.g., outside the ear canal of a user of the device) and may receive a second audio signal. The first and second audio signals may each include a voice audio signal (e.g., a speech component or user speech) from the user of the device. The voice audio signal included in the first audio signal and the voice audio signal included in the second audio signal may differ based on, for example, the different locations of the sensors that capture the first audio signal and the second audio signal (e.g., the locations of the sensors in relation to the user of the device and/or the environment of the user). The device may be configured to (i) select, based on the first audio signal and the second audio signal, a frequency limit (e.g., a voice coherence limit) between the first sensor and the second sensor, (ii) estimate, based on the first audio signal and the second audio signal, a transfer function between the first sensor and the second sensor, and (iii) apply an equalization based on the transfer function to a first portion of the first audio signal. The first portion of the first audio signal may correspond to a range of frequencies lower than the frequency limit. In this manner, the equalization may only be applied to the range of frequencies in the first audio signal lower than the selected voice coherence limit.

Many devices (e.g., wearable devices) may employ a denoising system configured to denoise an input audio signal (e.g., an audio signal received at one or more sensors of the wearable device) that includes speech originating from the user and provide a denoised output audio signal (e.g., an audio signal for transmission to another device) that includes the user speech. This type of denoising system may function admirably when the device is in a quiet environment. However, the denoising system may struggle when the device is in noisier environments (e.g., when a signal-to-noise ratio (SNR) of the received audio signals is relatively low, for example, between −10 dB and 2 dB, such as −6 dB, −3 dB, 1 dB, etc.). For example, when the environment of the device is windy (e.g., includes significant wind noise), and/or when the environment of the device is noisy (e.g., includes significant acoustic noise, such as when driving, in a restaurant, when using public transportation, etc.). The denoising system may struggle even more when both wind and environmental noise are present (e.g., when walking in a city street on a windy day).

In addition, even when an input audio signal that includes user speech has a relatively high SNR (e.g., such as when the input audio signal is captured at an internal sensor, such as a feedback microphone or a voice pickup unit (VPU)), or when the denoising system succeeds in producing a well-denoised output audio signal from the input audio signal, any user speech in the output audio signal frequently fails to sound natural, especially at relatively low frequencies. For example, the user speech in the output audio signal may sound muffled. As a result, the intelligibility and naturalness of any output signal that includes user speech may be impacted. This is especially problematic in the context of two way communication, where the wearable device should preferably capture audio that includes the user speech and output an audio signal that includes the user speech in an intelligible and natural form to one or more other devices (e.g., to facilitate a voice call). The intelligibility and naturalness of an output signal that includes user speech (or lack thereof) may also negatively impact the recording of voice messages and videos.

In certain aspects, a singular equalization (with a corresponding transfer function) may be applied to any input audio signal with user speech captured at a device to attempt to produce an output audio signal with natural-sounding user speech. However, the optimal equalization for applying to an input audio signal with user speech often varies significantly based on several factors. First, the optimal equalization to apply to an input audio signal with user speech may depend on the voice of the user from which the user speech originates. For example, the optimal equalization for applying to user speech from a male speaker may be different than the optimal equalization for applying to user speech from a female speaker (e.g., due to differences in tone and pitch between male voices and female voices). The age of a user may likewise also impact the optimal equalization for applying to user speech. Second, the optimal equalization to apply to an input audio signal with user speech may also depend on the content of the user speech (e.g., what words and/or syllables are being spoken by the user) or the mood of the user, even for the user is consistent. For example, the optimal equalization for applying to user speech from a user at a first time may be different than the optimal equalization for applying to user speech from the user at a second different time, as a result of differences in the content of the user speech (and/or the mood of the user) at the first time and the second time. As a result, an equalization that may be optimal for applying to an input audio signal with user speech from a first user in one scenario is likely not optimal (or even acceptable) for applying to an input audio signal with user speech from the first user or another user in another scenario.

The present disclosure may enable a wearable device to apply an adaptive equalization to an input audio signal with user speech captured at an internal sensor (e.g., an occluded sensor, such as a feedback microphone or a voice pickup unit (VPU)) to provide an output audio signal with enhanced speech naturalness (especially at relatively low frequencies), while leveraging the relatively high SNR of the input audio signal to also ensure the user speech is intelligible. As a result of using the adaptive equalization for enhanced speech naturalness described herein, the equalization applied to an input audio signal with user speech may be customized and tailored specifically to the user and to the user speech, thereby enabling the wearable device to provide an optimal output audio signal with increased user speech naturalness and high intelligibility regardless of the voice of the user and/or the content of the user speech. In some cases, the output audio signal may subsequently be denosied with a denoising system, and mixed with other audio signals to produce a denoised and mixed output audio signal that maintains the increased user speech naturalness and high user speech intelligibility. In addition, a trained machine-learning model may be applied to the denoised and mixed output audio signal to boost the SNR of the denoised and mixed output audio signal, to further improve the intelligibility of the user speech.

### An Example System

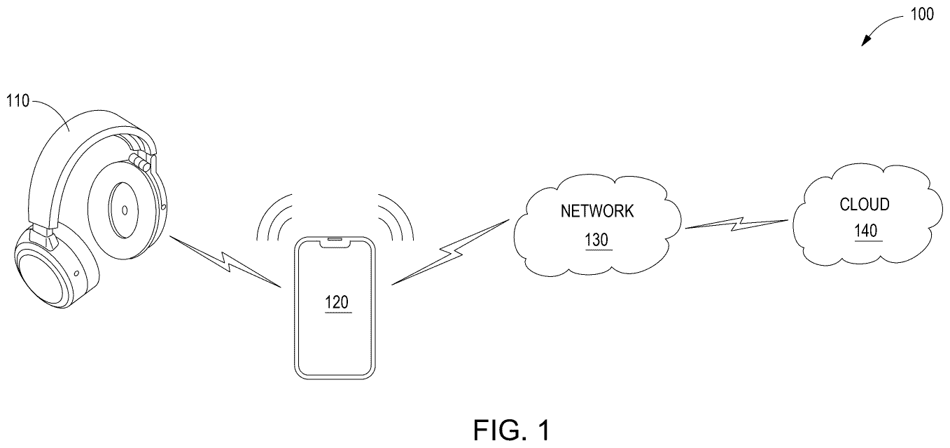

FIG. 1 illustrates an example system 100, in which aspects of the present disclosure may be implemented. As shown, system 100 includes one or more sound processing and playback devices 110 (e.g., a wireless audio device, such as a wearable device as shown in FIG. 1) communicatively coupled with a source device 120 (e.g., a computing device or user device, such as a smartphone, tablet, computer, television, or the like). Throughout the present disclosure, the sound processing and playback device 110 may be referred to simply as wearable device 110. The wearable device 110 may be configured to be worn by a user and may be a headset that includes two or more speakers and two or more sensors, as illustrated in FIG. 1. The source device 120 is illustrated as a smartphone or a tablet computer wirelessly paired with the wearable device 110. At a high level, the wearable device 110 may play audio content transmitted from the source device 120. The user may use the graphical user interface (GUI) on the source device 120 to select the audio content and/or adjust settings of the wearable device 110. The wearable device 110 provides soundproofing, active noise cancellation, and/or other audio enhancement features to play the audio content transmitted from the source device 120.

In certain aspects, the wearable device 110 includes voice activity detection (VAD) circuitry capable of detecting the presence of speech signals (e.g., human speech signals) in a sound signal received by sensors (not illustrated) of the wearable device 110. For instance, the sensors of the wearable device 110 may be implemented as microphones and may receive ambient and external sounds in the vicinity of the wearable device 110, including speech uttered by the user. The sound signal received by the sensors may have the speech signal mixed in with other sounds in the vicinity of the wearable device 110. Using the VAD, the wearable device 110 may detect and extract the speech signal from the received sound signal. In certain aspects, the VAD circuitry may be used to detect and extract speech uttered by the user in order to facilitate a voice call, voice chat between the user and another person, or voice commands for a virtual personal assistant (VPA), such as a cloud based VPA. In some cases, detections or triggers can include self-VAD (only starting up when the user is speaking, regardless of whether others in the area are speaking), active transport (sounds captured from transportation systems), head gestures, buttons, computing device based triggers (e.g., pause/un-pause from the phone), changes with input audio level, and/or audible changes in environment, among others. The voice activity detection circuitry may run or assist running the speech enhancement disclosed herein.

In certain aspects, the wearable device 110 includes speaker identification circuitry capable of detecting an identity of a speaker to which a detected speech signal relates to. For example, the speaker identification circuitry may analyze one or more characteristics of a speech signal detected by the VAD circuitry and determine that the user of the wearable device 110 is the speaker. In certain aspects, the speaker identification circuitry may use any of the existing speaker recognition methods and related systems to perform the speaker recognition.

The wearable device 110 further includes hardware and circuitry including processor(s)/processing system and memory configured to implement one or more sound management capabilities or other capabilities including, but not limited to, noise canceling circuitry (not shown) and/or noise masking circuitry (not shown), body movement detecting devices/sensors and circuitry (e.g., one or more accelerometers, one or more gyroscopes, one or more magnetometers, etc.), geolocation circuitry and other sound processing circuitry. The noise cancelling circuitry is configured to reduce unwanted ambient sounds external to the wearable device 110 by using active noise cancelling (also known as active noise reduction). The sound masking circuitry is configured to reduce distractions by playing masking sounds via the speakers of the wearable device 110. The movement detecting circuitry is configured to use devices/sensors such as an accelerometer, gyroscope, magnetometer, or the like to detect whether the user wearing the wearable device 110 is moving (e.g., walking, running, in a moving mode of transport, etc.) or is at rest and/or the direction the user is looking or facing. The movement detecting circuitry may also be configured to detect a head position of the user for use in determining an event, as will be described herein, as well as in extended reality (XR) applications (e.g., augmented reality (AR), virtual reality (VR), or mixed reality (MR) applications) where XR sound is played back based on a direction of gaze of the user.

In certain aspects, the wearable device 110 is wirelessly connected to the source device 120 using one or more wireless communication methods including, but not limited to, Bluetooth, Wi-Fi, Bluetooth Low Energy (BLE), other radio frequency (RF) based techniques, or the like. In certain aspects, the wearable device 110 includes a transceiver that transmits and receives data via one or more antennae in order to exchange audio data and other information with the source device 120.

In certain aspects, the wearable device 110 includes communication circuitry capable of transmitting and receiving audio data and other information from the source device 120. The wearable device 110 also includes an incoming audio buffer, such as a render buffer, that buffers at least a portion of an incoming audio signal (e.g., audio packets) in order to allow time for retransmissions of any missed or dropped data packets from the source device 120. For example, when the wearable device 110 receives Bluetooth transmissions from the source device 120, the communication circuitry typically buffers at least a portion of the incoming audio data in the render buffer before the audio is actually rendered and output as audio to at least one of the transducers (e.g., audio speakers) of the wearable device 110. This is done to ensure that even if there are RF collisions that cause audio packets to be lost during transmission, there is time for the lost audio packets to be retransmitted by the source device 120 before the lost audio packets have been rendered by the wearable device 110 for output by one or more acoustic transducers of the wearable device 110.

The wearable device 110 is illustrated as over-the-head headphones; however, the techniques described herein apply to other wearable devices, such as wearable audio devices, including any audio output device that fits around, on, in, or near an ear (including open-ear audio devices worn on the head or shoulders of a user) or other body parts of a user, such as head or neck. The wearable device 110 may take any form, wearable or otherwise, including standalone devices (including automobile speaker system), stationary devices (including portable devices, such as battery powered portable speakers), headphones (including over-ear headphones, on-ear headphones, in-ear headphones), earphones, earpieces, headsets (including XR headsets), goggles, headbands, earbuds, armbands, sport headphones, neckbands, hearing aids, or eyeglasses. In certain aspects, the wearable device 110 may be implemented as a banded headset with two cups each configured to deliver audio output.

In certain aspects, the wearable device 110 is connected to the source device 120 using a wired connection, with or without a corresponding wireless connection. The source device 120 may be a smartphone, a tablet computer, a laptop computer, a digital camera, or other computing device that connects with the wearable device 110. As shown, the source device 120 can be connected to a network 130 (e.g., the Internet) and may access one or more services over the network. As shown, these services can include one or more cloud 140 services.

In certain aspects, the source device 120 can access a cloud server in the cloud 140 over the network 130 using a mobile web browser or a local software application or “app” executed on the source device 120. In certain aspects, the software application or “app” is a local application that is installed and runs locally on the source device 120. In certain aspects, a cloud server accessible on the cloud 140 includes one or more cloud applications that are run on the cloud server. The cloud application may be accessed and run by the source device 120. For example, the cloud application can generate web pages that are rendered by the mobile web browser on the source device 120. In certain aspects, a mobile software application installed on the source device 120 or a cloud application installed on a cloud server, individually or in combination, may be used to implement the techniques for low latency Bluetooth communication between the source device 120 and the wearable device 110 in accordance with aspects of the present disclosure. In certain aspects, examples of the local software application and the cloud application include a gaming application, an audio XR application, and/or a gaming application with audio XR capabilities. The source device 120 may receive signals (e.g., data and controls) from the wearable device 110 and send signals to the wearable device 110.

### An Example Wearable Device

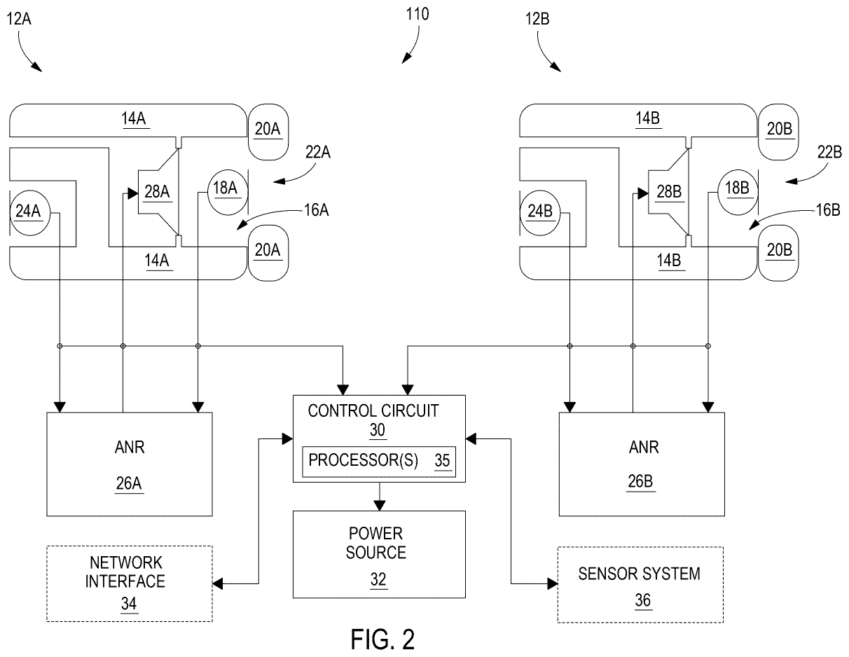

FIG. 2 illustrates an exemplary wearable device 110 and some of its components, in which aspects of the present disclosure may be implemented. Other components may be inherent in the wearable device 110 and not shown in FIG. 2. As shown, the wearable device 110 includes two earpieces 12A and 12B, each configured to direct sound towards an ear of the user. Reference numbers appended with an “A” or a “B” indicate a correspondence of the identified feature with a particular one of the earpieces 12 (e.g., a left earpiece 12A and a right earpiece 12B). Each earpiece 12 includes a casing 14 that defines a cavity 16. In some examples, one or more inner (e.g., internal) sensors 18 (e.g., inner microphone(s)) may be disposed within cavity 16. In implementations where the wearable device 110 is ear-mountable, an ear coupling 20 (e.g., an ear tip or ear cushion) may be attached to the casing 14 and surround an opening to the cavity 16. A passage 22 is formed through the ear coupling 20 and communicates with the opening to the cavity 16. In some examples, one or more outer sensors 24 are disposed on the casing in a manner that permits acoustic coupling to the environment external to the casing. The inner sensor(s) 18 and the outer sensor(s) 24 may each be implemented and/or referred to as a microphone, an accelerometer, a voice pickup unit (VPU), and/or an inertial measurement unit (IMU).

In implementations that include active noise reduction (ANR) (which may include or be referred to as active noise cancellation (ANC), controllable noise canceling (CNC), and/or transparency (e.g., aware) mode operation (where environmental sound is sensed and then reproduced to the user so the user is more environmentally aware and can hear others speaking and the like)), the inner sensor(s) 18 may be an internal microphone(s) or feedback microphone(s) and the outer sensor(s) 24 may be feedforward microphone(s). In such implementations, each earpiece 12 includes an ANR circuit 26 that is in communication with the inner sensor(s) 18 and the outer sensor(s) 24. The ANR circuit 26 receives an inner signal generated by the inner sensor(s) 18 and an outer signal generated by the outer sensor(s) 24 and performs an ANR process for the corresponding earpiece 12. The process includes providing a signal to an electroacoustic transducer 28 (e.g., speaker) disposed in the cavity 16 to generate an anti-noise acoustic signal that reduces or substantially prevents sound from one or more acoustic noise sources that are external to the earpiece 12 from being heard by the user. In addition to providing an anti-noise acoustic signal, the electroacoustic transducer 28 may utilize its sound-radiating surface for providing an audio output for playback (e.g., for a continuous audio feed). In some cases, the ANR described herein may include feedforward ANR (e.g., where noises from external sources may be reduced) and/or feedback ANR (e.g., where noises from external sources may be reduced and noise inside of the cavity 16 which includes the users'body generated noise (such as speech) is also reduced.

In certain aspects, the wearable device 110 may also include a control circuit 30. The control circuit 30 is in communication with the inner sensor(s) 18, outer sensor(s) 24, and electroacoustic transducers 28, and receives the inner and/or outer microphone signals. In some cases, the control circuit 30 includes one or more microcontroller(s) or processor(s) 35, including for example, a digital signal processor (DSP) and/or an advanced reduced instruction set computer (RISC) machine (ARM) chip. In some cases, the microcontroller(s)/processor(s) (or simply, processor(s)) 35 may include multiple chipsets for performing distinct functions. For example, the processor(s) 35 may include a DSP chip for performing music and voice related functions, and a co-processor such as an ARM chip (or chipset) for performing sensor related functions.

The control circuit 30 may also include analog to digital converters for converting the inner signals from the two inner sensors 18 and/or the outer signals from the two outer sensors 24 to digital format. In response to the received inner and/or outer microphone signals, the control circuit 30 (including processor(s) 35) may take various actions. For example, audio playback may be initiated, paused, or resumed, a notification to a user (e.g., wearer) may be provided or altered, and a device (e.g., a cellular phone, a handheld device, a wireless device, a laptop computer, a tablet, a smartphone, an Internet of things (IoT) device, a wearable device, an AR device, a VR device, etc.) in communication with the wearable device 110 may be controlled. The wearable device 110 may also include a power source 32. The control circuit 30 and power source 32 may be in one or both of the earpieces 12 or may be in a separate housing in communication with the earpieces 12. The wearable device 110 may also include a network interface 34 to provide communication between the wearable device 110 and one or more audio sources or other personal audio devices (e.g., source device 120 as illustrated in FIG. 1). The network interface 34 may be wired (e.g., Ethernet) or wireless (e.g., employ a wireless communication protocol such as IEEE 802.11, Bluetooth, Bluetooth Low Energy (BLE), or other local area network (LAN) or personal area network (PAN) protocols).

The network interface 34 is shown in phantom, as portions of the network interface 34 may be located remotely from the wearable device 110. The network interface 34 may provide for communication between the wearable device 110, audio sources, and/or other networked (e.g., wireless) speaker packages and/or other audio playback devices via one or more communications protocols. The network interface 34 may provide either or both of a wireless interface and a wired interface. The wireless interface may allow the wearable device 110 to communicate wirelessly with other devices in accordance with any communication protocol noted herein. In some particular cases, a wired interface may be used to provide network interface functions via a wired (e.g., Ethernet) connection.

In certain aspects, the network interface 34 may also include one or more network media processor(s) for supporting, e.g., Apple AirPlay® (a proprietary protocol stack/suite developed by Apple Inc., with headquarters in Cupertino, Calif., that allows wireless streaming of audio, video, and photos, together with related metadata between devices) or other known wireless streaming services (e.g., an Internet music service such as: Pandora®, a radio station provided by Pandora Media, Inc. of Oakland, Calif., USA; Spotify®, provided by Spotify USA, Inc., of New York, N.Y., USA); or vTuner®, provided by vTuner. com of New York, N.Y., USA); and network-attached storage (NAS) devices). For example, when a user connects an AirPlay® enabled device, such as an iPhone or iPad device, to the network, the user may then stream music to the network connected audio playback devices via Apple AirPlay®. Notably, the audio playback device can support audio-streaming via AirPlay® and/or DLNA's UPnP protocols, and all integrated within one device. Other digital audio coming from network packets may come straight from the network media processor(s) through (e.g., through a USB bridge) to the control circuit 30. As noted herein, in some cases, the control circuit 30 may include one or more processor(s) and/or microcontroller(s) (simply, “processor(s)” 35), which can include decoders, digital signal processors (DSPs) hardware/software, ARM processor(s) hardware/software, etc. for playing back (rendering) audio content at electroacoustic transducers 28. In some cases, the network interface 34 may also include Bluetooth circuitry for Bluetooth applications (e.g., for wireless communication with a Bluetooth enabled audio source such as a smartphone or tablet). In operation, streamed data can pass from the network interface 34 to the control circuit 30, including the processor(s) or microcontroller(s) (e.g., processor(s) 35). The control circuit 30 may execute instructions (e.g., for performing, among other things, digital signal processing, decoding, and equalization functions), including instructions stored in a corresponding memory (which may be internal to control circuit 30 or accessible via network interface 34 or other network connection (e.g., cloud-based connection). The control circuit 30 may be implemented as a chipset of chips that include separate and multiple analog and digital processors. The control circuit 30 may provide, for example, for coordination of other components of the wearable device 110, such as control of user interfaces (not shown) and applications run by the wearable device 110.

In addition to a processor(s) and/or microcontroller(s), control circuit 30 may also include one or more digital-to-analog (D/A) converters for converting the digital audio signal to an analog audio signal. This audio hardware may also include one or more amplifiers which provide amplified analog audio signals to the electroacoustic transducer(s) 28, which each include a sound-radiating surface for providing an audio output for playback. In addition, the audio hardware may include circuitry for processing analog input signals to provide digital audio signals for sharing with other devices.

The memory in control circuit 30 may include, for example, flash memory and/or non-volatile random access memory (NVRAM). In some implementations, instructions (e.g., software) are stored in an information carrier. The instructions, when executed by one or more processing devices (e.g., the processor(s) or microcontroller(s) in control circuit 30), perform one or more processes, such as those described elsewhere herein. The instructions can also be stored by one or more storage devices, such as one or more (e.g., non-transitory) computer or machine-readable mediums (for example, the memory, or memory on the processor(s)/microcontroller(s)). As described herein, the control circuit 30 (e.g., memory, or memory on the processor(s)/microcontroller(s)) may include a control system including instructions for controlling directional audio selection functions according to various particular implementations. It is understood that portions of the control circuit 30 (e.g., instructions) could also be stored in a remote location or in a distributed location and could be fetched or otherwise obtained by the control circuit 30 (e.g., via any communications protocol described herein) for execution. The instructions may include instructions for controlling device functions based upon detected don/doff events (i.e., the software modules include logic for processing inputs from a sensor system to manage audio functions), as well as digital signal processing and equalization.

The wearable device 110 may also include a sensor system 36 coupled with control circuit 30 for detecting one or more conditions of the environment proximate the wearable device 110. The sensor system 36 may include inner sensor(s) 18 and/or outer sensors 24, sensors for detecting inertial conditions at the personal audio device, and/or sensors for detecting conditions of the environment proximate the wearable device 110, as described herein. Sensor system 36 may also include one or more proximity sensors, such as a capacitive proximity sensor or an IR sensor, and/or one or more optical sensors.

The sensors may be on-board the wearable device 110 or may be remote or otherwise wirelessly (or hard-wired) connected to the wearable device 110. As described further herein, sensor system 36 may include a plurality of distinct sensor types for detecting proximity information, inertial information, environmental information, or commands at the wearable device 110. In particular implementations, sensor system 36 may enable detection of user movement, including movement of a user's head or other body part(s). Portions of sensor system 36 may incorporate one or more movement sensors, such as accelerometers, gyroscopes and/or magnetometers and/or a single IMU having three-dimensional (3D) accelerometers, gyroscopes and a magnetometer.

In various implementations, the sensor system 36 can be located at the wearable device 110 (e.g., where a proximity sensor is physically housed in the wearable device 110). In some examples, the sensor system 36 is configured to detect a change in the position of the wearable device 110 relative to the user's head (e.g., detect the device operating state). Data indicating the change in the position of the wearable device 110 may be used to trigger a command function, such as activating an operating mode of the wearable device 110, modifying playback of audio at the wearable device 110 (e.g., by modifying the audio, noise cancellation (e.g., ANR), or transparency of the wearable device), or controlling a power function of the wearable device 110.

The sensor system 36 may also include one or more interface(s) for receiving commands at the wearable device 110. For example, sensor system 36 may include an interface permitting a user to initiate functions of the wearable device 110. In a particular example implementation, the sensor system 36 may include, or be coupled with, a capacitive touch interface for receiving tactile commands on the wearable device 110.

In other implementations, as illustrated in the phantom depiction in FIG. 2, one or more portions of the sensor system 36 may be located at another device capable of indicating movement and/or inertial information about the user of the wearable device 110. For example, in some cases, the sensor system 36 may include an IMU physically housed in a hand-held device such as a smart device (e.g., smart phone, tablet, etc.) a pointer, or in another wearable audio device. In particular example implementations, at least one of the sensors in the sensor system 36 may be housed in a wearable audio device distinct from the wearable device 110, such as where wearable device 110 includes headphones and an IMU is located in a pair of glasses, a watch, or other wearable electronic device.

In certain aspects, the control circuit 30 is in communication with the inner sensor(s) 18 and receives the two inner signals. Alternatively, the control circuit 30 may be in communication with the outer sensors 24 and receive the two outer signals. In another alternative, the control circuit 30 may be in communication with both the inner sensor(s) 18 and outer sensors 24 and receives the two inner and two outer signals. It should be noted that in some implementations, there may be multiple inner and/or outer microphones in each earpiece 12. As noted herein, the control circuit 30 may include one or more microcontroller(s) or processor(s) having a DSP and the inner signals from the two inner sensor(s) 18 and/or the outer signals from the two outer sensors 24 are converted to digital format by analog to digital converters. In response to the received inner and/or outer signals, the control circuit 30 may take various actions. For example, the power supplied to the wearable device 110 may be reduced upon a determination that one or both earpieces 12 are off-head. In another example, full power may be returned to the wearable device 110 in response to a determination that at least one earpiece becomes on head. Other aspects of the wearable device 110 may be modified or controlled in response to determining that a change in the operating state of the earpiece 12 has occurred. For example, ANR functionality may be enabled or disabled, audio playback may be initiated, paused or resumed, a notification to a wearer may be altered, and a device (e.g., a cellular phone, a handheld device, a wireless device, a laptop computer, a tablet, a smartphone, an Internet of things (IoT) device, a wearable device, an AR device, a VR device, etc.) in communication with the wearable device 110 may be controlled. As illustrated, the control circuit 30 generates a signal that is used to control a power source 32 for the wearable device 110. The control circuit 30 and power source 32 may be in one or both of the earpieces 12 or may be in a separate housing in communication with the earpieces 12.

### Example Operations for Using Adaptive Equalization to Provide Enhanced Speech Naturalness

Certain aspects of the present disclosure provide techniques, including devices and systems implementing the techniques, for using adaptive equalization to provide enhanced speech naturalness. Such techniques may involve receiving (e.g., capturing) first and second audio signals at two (or more) sensors included in a device. The first and second audio signals may each include a voice audio signal (e.g., a speech component or user speech) from the user of the device. The device may be configured to (i) select, based on the first and second audio signals, a frequency limit between the first and second sensors, (ii) estimate, based on the first and second audio signals, a transfer function between the first and second sensors, and (iii) apply an equalization based on the transfer function to a first portion of the first audio signal. The first portion of the first audio signal may correspond to a range of frequencies lower than the frequency limit.

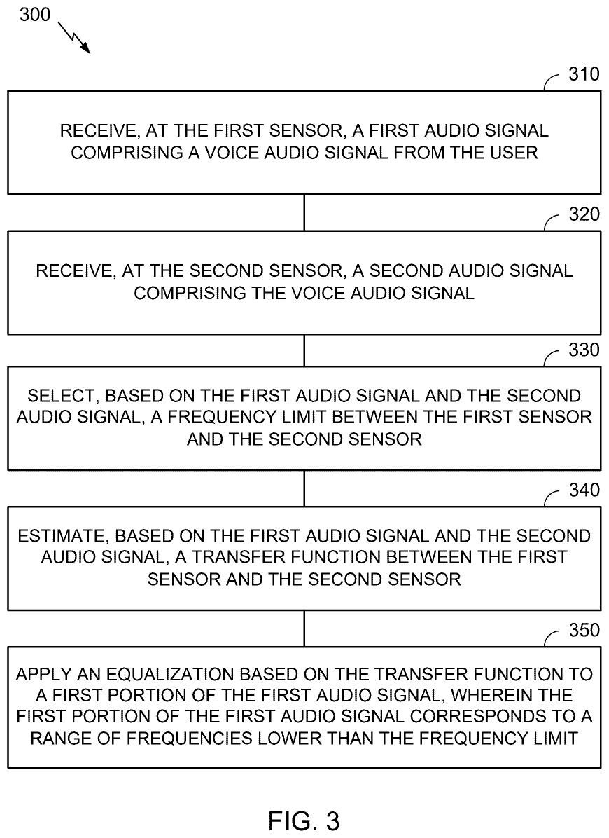

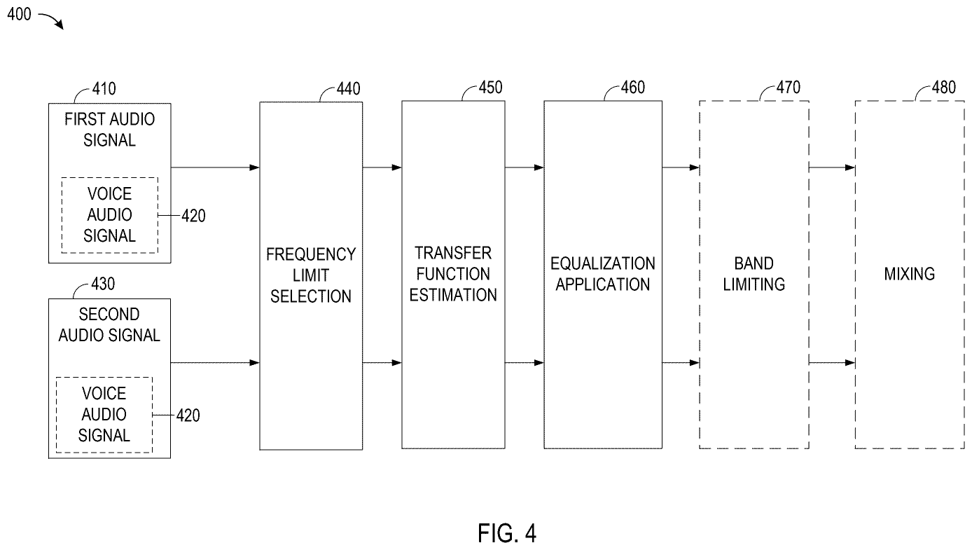

FIG. 3 illustrates example operations 300 for speech enhancement performed by a device (e.g., the wearable device 110 of FIGS. 1 and 2), according to certain aspects of the present disclosure. FIG. 4 is a block diagram of an example process flow 400 for speech enhancement during the operations 300 of FIG. 3, according to certain aspects of the present disclosure. Therefore, FIG. 3 and FIG. 4 are herein described together for clarity. The operations 300 and the process flow 400 may be performed by a wearable device (e.g., the device 110 of FIG. 1 and FIG. 2), by a control circuit (e.g., control circuit 30) of the device (e.g., using one or more processors, individually or collectively, included in the control circuit). The operations 300 and the process flow 400 may be utilized by the device continuously, periodically, or selectively. In some cases, the operations 300 may be performed when a user of the wearable device is speaking (e.g., producing a voice signal).

The operations 300 may include, at block 310, receiving, at a first sensor (e.g., inner sensor(s) 18) included in the wearable device, a first audio signal 410. In certain aspects, the first sensor may include or be implemented by an internal sensor. The internal sensor may be implemented by, for example, a bone conduction sensor and/or transducer (e.g., an internal microphone inside an ear canal of a user of the device, an internal microphone facing the ear canal on an around ear device, a voice band accelerometer outside the ear canal, a voice pickup unit (VPU), a feedback microphone, or the like).

At block 320, the operations 300 may include receiving, at a second sensor (e.g., outer sensor(s) 24) included in the wearable device, a second audio signal 430. In certain aspects, the second sensor may include or be implemented by an external microphone disposed outside the ear canal of the user of the device (e.g., implemented and/or referred to herein as an “external microphone,” an “outside microphone,” or an “out-of-user canal microphone”). In other aspects, the second sensor may include or be implemented by or a beamformed microphone. In some cases, the second sensor may include or be implemented by a combination of external microphones and/or a combination of beamformed microphones. The first audio signal 410 and the second audio signal 430 may each include a voice audio signal 420 (e.g., a speech component or user speech) originating from the user of the device. The voice audio signal 420 included in the first audio signal 410 and the voice audio signal 420 included in the second audio signal 430 may differ based on, for example, the different locations of the sensors that capture the first audio signal 410 and the second audio signal 430 (e.g., the locations of the sensors in relation to the user of the device and/or the environment of the user).

At block 330, the operations 300 may include selecting, based on the first audio signal 410 and the second audio signal 430, a frequency limit (e.g., a voice coherence limit) between the first sensor and the second sensor (e.g., block 440). In this manner, the operations 300 may determine the range of frequencies (or until what frequency point) that the equalization may be applied to at block 350, such that the equalization may be applied to the frequencies in which the voice audio signal 420 in the first audio signal 410 and in the second audio signal 430 has sufficient signal integrity.

According to certain aspects, the operations 300 may further include selecting the frequency limit between the first sensor and the second sensor at block 330 when the first audio signal 410 and the second audio signal 430 each include a level of noise that is below a threshold. In this manner, the operations 300 may determine that any noise (e.g., wind and/or environmental noise) present in the first audio signal 410 and the second audio signal 430 is sufficiently low, to further ensure that the voice audio signal 420 in the first audio signal 410 and the second audio signal 430 has sufficient signal integrity for block 340 and block 350.

At block 340, the operations 300 may include estimating, based on the first audio signal 410 and the second audio signal 430, a transfer function between the first sensor and the second sensor (e.g., block 450). In certain aspects, to estimate the transfer function between the first sensor and the second sensor, adaptive filtering may be used. In these aspects, the adaptive filtering may, in some cases, involve denoising the first audio signal 410 and/or the second audio signal 430 (or the mixed audio signal described herein) to remove any noise (e.g., wind and/or environmental noise) present. In this manner, the denoising burden for subsequent signal processing may be eliminated (or at least reduced). The frequency limit selected at block 330 may help ensure (or in other words validate) the frequencies of the first audio signal 410 for which the transfer function estimation at block 340 (which may involve adaptive filtering, such as adaptive filtering), will function properly and produce an acceptable transfer function estimation. In some cases, to estimate the transfer function between the first sensor and the second sensor at block 340, uncorrelated noise between the first audio signal 410 and the second audio signal 430 may be denoised (e.g., using filtering, such as adaptive filtering).

At block 350, the operations 300 may include applying an equalization based on the transfer function to a first portion of the first audio signal 410 (e.g., block 460). The first portion of the first audio signal 410 may correspond to a range of frequencies lower than the frequency limit. In this manner, the equalization may be applied based on the frequency limit selected at block 330.

According to certain aspects, the operations 300 may further include band limiting the first audio signal 410 to the first portion of the first audio signal 410 such that a second portion of the first audio signal 410 corresponding to a range of frequencies higher than the frequency limit is removed (e.g., block 470). In this manner, the operations 300 may ensure that the remaining first portion of the first audio signal 410 may be the robust, natural-sounding, and intelligible part of the voice audio signal 420 in the first audio signal 410, and the second portion of the first audio signal 410 may be discarded and not undergo further signal processing.

Any combination of the operations 300 may produce the first portion of the first audio signal 410, which may be referred to and understood to be an output audio signal. After the operations 300 are performed (or as part of the operations 300), the first audio signal 410 may be used, for example, during communication with another device or used to generate a voice message or video, or may undergo additional signal processing (e.g., mixing and/or denoising).

According to certain aspects, the operations 300 may further include mixing the first portion of the first audio signal 410 with at least a first portion of the second audio signal 430 to form a mixed audio signal (e.g., block 480). The first portion of the second audio signal 430 may correspond to a range of frequencies higher than the frequency limit. In some cases, the low frequencies (e.g., the frequencies below the frequency limit) of the first audio signal 410 may be mixed with the high frequencies (e.g., the frequencies above the frequency limit) of the second audio signal 430 to form the mixed audio signal. In other cases, the low frequencies (e.g., the frequencies below the frequency limit) of the first audio signal 410 may be mixed with both the entirety of the second audio signal 430 (e.g., both the range of frequencies above the frequency limit and the range of frequencies below the frequency limit) to form the mixed audio signal. In certain aspects, one or more additional audio signals (received at one or more additional sensors of the wearable device) may also be included in the mixing with the first portion of the first audio signal 410 and the first portion of the second audio signal 430 to form the mixed audio signal. That is, the first portion of the first audio signal 410 may be mixed with at least part of any other audio signal (received at any external and/or beamformed sensor).

In some cases, the first portion of the first audio signal 410 from block 350 may be mixed with the entirety of the second audio signal 430 to form the mixed audio signal, whereas in other cases, the first portion of the first audio signal 410 from block 350 may be mixed with only the first portion of the second audio signal 430 to form the mixed audio signal. In certain aspects, bandwidth extension and/or bandwidth extraction may be used on the first portion of the first audio signal 410 (and/or any portion of the first audio signal 410) and/or at least the first portion of the second audio signal 430 to form the mixed audio signal.

According to certain aspects, the operations 300 may further include additional denoising of the first portion of the first audio signal 410 (or the mixed audio signal described above) to further work to remove any noise (e.g., wind and/or environmental noise) present.

According to certain aspects, the operations 300 may further include increasing, using a machine-learning model or a signal processing model, a signal-to-noise ratio (SNR) of the mixed audio signal. In this manner, the SNR of the mixed audio signal may be boosted (e.g., to increase the intelligibility of the voice audio signal 420 in the mixed audio signal), for example, when the SNR of the mixed audio signal is too low. In some cases, the machine-learning model may be a trained machine-learning model and may be implemented by a deep learning model. The trained machine-learning model may use various machine learning techniques based on artificial neural networks. For example, the trained machine-learning model, when implemented as a deep learning model, may include deep learning architectures, such as deep neural networks, deep belief networks, deep reinforcement learning, recurrent neural networks, convolutional neural networks, transformers, and the like.

### Additional Considerations

It is noted that, descriptions of aspects of the present disclosure are presented above for purposes of illustration, but aspects of the present disclosure are not intended to be limited to any of the disclosed aspects. Many modifications and variations will be apparent to those of ordinary skill in the art without departing from the scope and spirit of the described aspects.

In the preceding, reference is made to aspects presented in this disclosure. However, the scope of the present disclosure is not limited to specific described aspects. Aspects of the present disclosure can take the form of an entirely hardware aspect, an entirely software aspect (including firmware, resident software, micro-code, etc.) or an aspect combining software and hardware aspects that can all generally be referred to herein as a “component,” “circuit,” “module” or “system.” Furthermore, aspects of the present disclosure can take the form of a computer program product embodied in one or more computer readable medium(s) having computer readable program code embodied thereon.

As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples of a computer readable storage medium include: an electrical connection having one or more wires, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the current context, a computer readable storage medium can be any tangible medium that can contain, or store a program.

The flowchart and block diagrams in the Figures illustrate the architecture, functionality and operation of possible implementations of systems, methods and computer program products according to various aspects. In this regard, each block in the flowchart or block diagrams can represent a module, segment or portion of code, which comprises one or more executable instructions for implementing the specified logical function(s). In some alternative implementations the functions noted in the block can occur out of the order noted in the figures. For example, two blocks shown in succession can, in fact, be executed substantially concurrently, or the blocks can sometimes be executed in the reverse order, depending upon the functionality involved. Each block of the block diagrams and/or flowchart illustrations, and combinations of blocks in the block diagrams and/or flowchart illustrations can be implemented by special-purpose hardware-based systems that perform the specified functions or acts, or combinations of special purpose hardware and computer instructions.

What is claimed is:

1. A wearable audio device of a user comprising:
a first sensor;
a second sensor; and
one or more processors being configured, individually or collectively, to:
receive, at the first sensor, a first audio signal comprising a voice audio signal from the user;
receive, at the second sensor, a second audio signal comprising the voice audio signal;
select, based on the first audio signal and the second audio signal, a frequency limit between the first sensor and the second sensor;
estimate, based on the first audio signal and the second audio signal, a transfer function between the first sensor and the second sensor; and
apply an equalization based on the transfer function to a first portion of the first audio signal, wherein the first portion of the first audio signal corresponds to a range of frequencies lower than the frequency limit.

2. The wearable audio device of claim 1, wherein the one or more processors, individually or collectively, are configured to select the frequency limit between the first sensor and the second sensor when the first audio signal and the second audio signal each comprise a level of noise that is below a threshold.

3. The wearable audio device of claim 1, wherein the one or more processors, individually or collectively, are further configured to:
band limit the first audio signal to the first portion of the first audio signal such that a second portion of the first audio signal corresponding to a range of frequencies higher than the frequency limit is removed.

4. The wearable audio device of claim 1, wherein the one or more processors, individually or collectively, are further configured to one of:
mix the first portion of the first audio signal with at least a first portion of the second audio signal to form a mixed audio signal, wherein the first portion of the second audio signal corresponds to a range of frequencies higher than the frequency limit.

5. The wearable audio device of claim 4, wherein the one or more processors, individually or collectively, are further configured to:
increase, using a machine-learning model or a signal processing model, a signal-to-noise ratio (SNR) of the mixed audio signal.

6. The wearable audio device of claim 1, wherein to estimate the transfer function between the first sensor and the second sensor, the one or more processors are configured, individually or collectively, to use adaptive filtering.

7. The wearable audio device of claim 1, wherein to estimate the transfer function between the first sensor and the second sensor, the one or more processors are further configured, individually or collectively, to denoise uncorrelated noise between the first audio signal and the second audio signal.

8. The wearable audio device of claim 1, wherein the first sensor comprises a bone conduction sensor.

9. The wearable audio device of claim 8, wherein the bone conduction sensor comprises one of: an internal microphone disposed inside an ear canal of the user, a microphone facing the ear canal, a voice band accelerometer disposed outside the ear canal, a voice pickup unit (VPU), or a feedback microphone.

10. The wearable audio device of claim 1, wherein the second sensor comprises an external microphone or a combination of external microphones disposed outside an ear canal of the user.

11. A method of using a wearable audio device, the method comprising:
receiving, at a first sensor of the wearable audio device, a first audio signal comprising a voice audio signal from a user of the wearable audio device;
receiving, at a second sensor of the wearable audio device, a second audio signal comprising the voice audio signal;
selecting, based on the first audio signal and the second audio signal, a frequency limit between the first sensor and the second sensor;
estimating, based on the first audio signal and the second audio signal, a transfer function between the first sensor and the second sensor; and
applying an equalization based on the transfer function to a first portion of the first audio signal, wherein the first portion of the first audio signal corresponds to a range of frequencies lower than the frequency limit.

12. The method of claim 11, further comprising:
selecting the frequency limit between the first sensor and the second sensor when the first audio signal and the second audio signal each comprise a level of noise that is below a threshold.

13. The method of claim 11, further comprising:
band limiting the first audio signal to the first portion of the first audio signal such that a second portion of the first audio signal corresponding to a range of frequencies higher than the frequency limit is removed.

14. The method of claim 11, further comprising:
mixing the first portion of the first audio signal with at least a first portion of the second audio signal to form a mixed audio signal, wherein the first portion of the second audio signal corresponds to a range of frequencies higher than the frequency limit.

15. The method of claim 14, further comprising:
increasing, using a trained machine-learning model, a signal-to-noise ratio (SNR) of the mixed audio signal.

16. A non-transitory computer-readable medium comprising computer-executable instructions that, when executed by one or more processors of a wearable audio device, cause the wearable audio device to perform a method, the method comprising:
receiving, at a first sensor of the wearable audio device, a first audio signal comprising a voice audio signal from a user of the wearable audio device;
receiving, at a second sensor of the wearable audio device, a second audio signal comprising the voice audio signal;
selecting, based on the first audio signal and the second audio signal, a frequency limit between the first sensor and the second sensor;
estimating, based on the first audio signal and the second audio signal, a transfer function between the first sensor and the second sensor; and
applying an equalization based on the transfer function to a first portion of the first audio signal, wherein the first portion of the first audio signal corresponds to a range of frequencies lower than the frequency limit.

17. The non-transitory computer-readable medium of claim 16, wherein the method further comprises:
selecting the frequency limit between the first sensor and the second sensor when the first audio signal and the second audio signal each comprise a level of noise that is below a threshold.

18. The non-transitory computer-readable medium of claim 16, wherein the method further comprises:
band limiting the first audio signal to the first portion of the first audio signal such that a second portion of the first audio signal corresponding to a range of frequencies higher than the frequency limit is removed.

19. The non-transitory computer-readable medium of claim 16, wherein the method further comprises:
mixing the first portion of the first audio signal with at least a first portion of the second audio signal to form a mixed audio signal, wherein the first portion of the second audio signal corresponds to a range of frequencies higher than the frequency limit.

20. The non-transitory computer-readable medium of claim 19, wherein the method further comprises:
increasing, using a trained machine-learning model, a signal-to-noise ratio (SNR) of the mixed audio signal.
